(19) United States
(12) Patent Application Publication
(10) Pub. No.: US 2026/0251987 A1
(43) Pub. Date: Aug. 27, 2026

(54) A PELLICLE CLEANING SYSTEM

(71) Applicant: ASML NETHERLANDS B.V., Veldhoven (NL)

(72) Inventors: Edwin Edwin TE SLIGTE, Waalre (NL); Alexander Ludwig KLEIN, Eindhoven (NL); Paul Alexander VERMEULEN, Eindhoven (NL); Abraham Jan WOLF, Nuenen (NL); Ilja GRISIN, Eindhoven (NL)

(73) Assignee: ASML NETHERLANDS B.V., Veldhoven (NL)

(21) Appl. No.: 18/726,728

(22) PCT Filed: Jan. 5, 2023
(86) PCT No.: PCT/EP2023/050198

§ 371 Date: Jul. 3, 2024

(30) Foreign Application Priority Data
Jan. 25, 2022 (EP) 22153208.8
Jul. 8, 2022 (EP) 22183953.3
Aug. 4, 2022 (EP) 22188666.6

(51) Int. Cl. G03F 7/00; B08B 7/00; G03F 1/86

(52) U.S. Cl. CPC G03F 7/70925; B08B 7/0042; G03F 1/86; G03F 7/70983

(57) ABSTRACT

A cleaning system for cleaning a component related to a lithographic process such as a pellicle, reticle, wafer or another lithographic component, the system including at least one radiation emitter configured to, in use, irradiate a region of the component so as to cause thermomechanical vibrations in the component and/or induce sputtering of contaminants present on the component.

### CROSS-REFERENCE TO RELATED APPLICATIONS

This application claims priority of EP application 22153208.8 which was filed on Jan. 25, 2022 and EP application 22183953.3 which was filed on Jul. 8, 2022 and EP application 22188666.6 which was filed on Aug. 4, 2002 and which are incorporated herein in their entirety by reference.

### FIELD

The present invention relates to a cleaning system for cleaning a component related to a lithographic process and method which uses radiation to cause thermomechanical vibrations in the component and/or induce sputtering of contaminants present on the component.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask, which may alternatively be referred to as a reticle) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Patterning devices are typically protected by a pellicle. A pellicle comprises a thin membrane which is substantially transparent to lithographic radiation. Pellicles prevent particles (and other contaminants) from falling onto, or otherwise contaminating, the patterning device. Through prolonged use, particles (which are prevented from contaminating the patterning device) accumulate on components of the lithographic apparatus, for example, the pellicle, and/or substrate patterned by the lithographic apparatus. Accumulation of particles on the pellicle (for example) can result in defects in the pattern produced on the substrate.

In some lithographic apparatus, multiple wafers of substrate are mounted on a substrate table at once and patterned by a single patterning device. In such lithographic apparatus, a single defect at the reticle level may result in corresponding defects in the patterns produced on each wafer of substrate.

Contaminants may also accumulate on other components of the lithographic apparatus causing defects in the pattern produced on the wafer by similar or other means.

Prior to use in a lithographic apparatus, a pellicle may be tested for structural integrity. Testing may involve applying a relatively small difference in ambient pressure to either side of a membrane of the pellicle. The pressure may induce a deformation in the pellicle. The deformation may be a static deformation i.e. approximately constant during a time in which the pressure is applied. The pellicle may break if the pellicle has less than a required structural integrity. Inducing a deformation in this way may not test the structural integrity of the pellicle across a whole surface of the pellicle in the same way. As a result, a pellicle that has passed the test for structural integrity may break during use in a lithographic apparatus, thus causing a period of time when the lithographic apparatus cannot be used as intended.

It is an object of techniques described in this disclosure to obviate or mitigate one or more of the problems set out herein.

### SUMMARY

In an example described herein there is a cleaning system for cleaning a component related to a lithographic process comprising at least one radiation emitter configured to, in use, irradiate a region of the component so as to cause thermomechanical vibrations in the component and/or induce sputtering of contaminants present on the component. Advantageously, the cleaning system may allow for the cleaning of the component.

In another example described herein there is a system for testing structural integrity of a component related to a lithographic process comprising: at least one radiation emitter configured to, in use, irradiate a region of the component so as to cause thermomechanical vibrations in the component. Beneficially, testing structural integrity of the component may indicate the ultimate tensile strength of the component. The testing may be destructive testing. Advantageously, testing may avoid the negative consequences of using deficient components.

The component may be a component configured for use in a lithographic apparatus, a lithographic tool or a metrology tool. The component may be a substrate configured to be patterned by a lithographic apparatus or a substrate already patterned by a lithographic apparatus. The component may also be a component for storing and/or transporting a component related to a lithographic process, for example, a reticle pod or pellicle pod. The lithographic apparatus and/or the lithographic process may use DUV or EUV radiation. For example, the component may be a reticle, a pellicle, a reticle clamp or a pellicle frame. The component may have a finite coefficient of thermal expansion.

The at least one radiation emitter may be a heater (i.e. the radiation emitter may emit heat or radiation that heats the component) and/or the at least one radiation emitter may emit ions (i.e. the component may be irradiated by ions from the radiation emitter). The contaminants may not be removed entirely from the component by the sputtering. Binding forces (binding the contaminants to the component) may be reduced in strength by sputtering.

The component may be pellicle. Advantageously, the cleaning system may allow for the cleaning of pellicles to minimize defects in the wafers patterned by lithographic apparatus.

The system may further comprise a holder configured to hold the component. Beneficially, the holder may secure the component in a fixed position relative to the heater thereby ensuring the region of the component heated by the heated is consistently the same region.

The at least one radiation emitter may comprise a heater configured to, in use, irradiate a region of the component so as to cause thermomechanical vibrations in the component.

The heater may be a source of electromagnetic radiation. The heater may be a laser. Beneficially, this may allow for the cleaning of components using readily available and inexpensive apparatus (e.g. without use of EUV light). This in turn may maximize the availability of lithographic apparatus for patterning wafers.

The radiation provided by the heater may have a frequency of 300 GHz to 4300 THz. Advantageously, a greater proportion of light of such frequencies may be absorbed by components, thereby increasing the amplitude of thermomechanical vibrations and improving the cleaning effect.

The radiation provided by the heater may have an average power between 1 mW and 200 W. The average power may include, for periodic heating, contributions from when the component is not being heated and from when the component is being heated. In other words, the power of the heater while the heater is applying heat may be higher than the average power.

The radiation provided by the heater may be pulsed. In other words, the heater may heat the region of the component periodically. For example, the heater may comprise a source of pulsed radiation such as a pulsed laser.

The radiation may have a pulse frequency between 1 Hz and 1 MHz.

Each pulse of the radiation may have a duration between 1 fs and 10 μs. Beneficially, such radiation properties may be optimal for inducing thermomechanical vibrations for cleaning components.

The holder may be positioned such that contaminants cleaned from the component are removed from a vicinity of the component under the force of gravity. Advantageously this may prevent removed contaminants from re-contaminating the component (and/or other components) after removal.

The heater may be configured to provide a plurality of radiation beams. This may allow for multiple regions of a single component to be heated (and/or to allow for multiple components to be heated) simultaneously so as to more efficiently clean one or more components.

The heater may comprise a plurality of heaters to generate one or more of the plurality of radiation beams.

The heater may comprise one or more beam splitting and/or redirecting optics to generate one or more of the plurality of radiation beams. For example, the holder may be configured to hold the component between the heater and beam redirection optics (e.g. a mirror) to allow two sides of the component to be heated by a single radiation source.

The holder may be one of a plurality of holders. The heater may be configured to, in use, periodically heat a region of each of a plurality of respective components, each one of the plurality respective components held in one of the plurality of holders. This may allow for multiple components to be cleaned at once. This may be particularly advantageous in a batch-cleaning process.

The system may be configured such that, in use, different ones of the plurality of radiation beams are incident on different ones of the plurality of components.

The heater may be configured to heat different ones of the plurality of components with different wavelengths. This may allow for different types of components, which absorb different wavelengths, to be cleaned at once.

The at least one radiation emitter may comprise an ion source configured to, in use, direct ions at a region of the component so as to induce sputtering of contaminants present on the component. Beneficially, the ions may cause a cleaning effect and/or improve a cleaning effect provided by other radiation emitters (e.g. a heater). The ions may, for example, reduce a binding force binding a contaminant to the component so that contaminants (that would not otherwise be removed by the heater) may be removed by the heater.

The ions may be ions of noble gas elements. For example, the ions may be positive Argon ions, positive Helium ions and/or positive Neon ions.

The ion source may be configured to, in use, direct ions at a region of a first side of the component so as to induce sputtering of contaminants present on a second side of the component.

The ion source may be configured to, in use, direct ions to a region of a first side of the component so as to induce sputtering of contaminants present on the first side of the component.

The at least one radiation emitter may comprise: a heater configured to, in use, heat a region of the component so as to cause thermomechanical vibrations in the component; and an ion source configured to, in use, irradiate a region of the component with ions so as to induce sputtering of contaminants present on the component.

The system may further comprise a housing, wherein the heater and holder are contained within the housing.

The housing may comprise a load lock chamber.

The system may further comprise a vacuum pump. Alternatively, the system may comprise a nitrogen or hydrogen source to create a nitrogen or hydrogen atmosphere within the housing.

The system may further comprise a gas exhaust to remove contaminants.

The system may further comprise metrology for measuring radiation emitted by the radiation emitter.

The system may further comprise metrology for measuring contamination on, or removed from, the component. Such metrology may be used to provide feedback for, e.g. dose control and to optimize cleaning times by avoiding unnecessary cleaning.

The system may further comprise an adjustor to adjust a slit width of the radiation between a first slit width and a second slit width. For example, the component may be cleaned using the system and the structural integrity of the component may be tested using the system. The cleaning and testing may be carried out in any order. Beneficially, the method may provide a clean component which has been screened for defects. For example, the component may be cleaned using the system and the structural integrity of a second component may be tested using the same system. Beneficially, the method may provide for cleaning and testing of components. In other words, the system may be used for different purposes. Beneficially, the system may allow for testing of the structural integrity of a component prior to cleaning of the same component or another component. Advantageously, by using the system in this way, any defective components may be removed sooner and thus saving resources compared to cleaning all components prior to screening for defective components.

In another example described herein there is a method of cleaning a component related to a lithographic process comprising irradiating a region of the component so as to: induce thermomechanical vibrations in the component; and/or induce sputtering of contaminants present on the component.

In another example described herein there is a method of testing the structural integrity of a component related to a lithographic processing comprising irradiating a region of the component so as to induce thermomechanical vibrations in the component.

Irradiating a region of the component may comprise heating the region of the component so as to induce thermomechanical vibrations in the component.

The heating may comprise providing one or more pulses of a pulsed heater. In other words, the region of the component may be heated periodically.

Periodically heating of the region of the component may be performed over a time between 20 seconds and 1 hour. Advantageously, 20 seconds may be long enough to ensure contaminants are removed from the component.

The method may further comprising heating a second region of the component with the heater. Heating the component with radiation may further comprise periodically heating a second region of the component for between 20 seconds and 1 hour. Beneficially, heating a second region of the component may ensure all regions of the component have been outside of a region being irradiated (where the cleaning effect is best) and therefore all regions may be cleaned adequately.

Irradiating a region of the component may comprise directing ions at the region of the component so as to induce sputtering of contaminants present on the component.

Irradiating a region of the component may comprise directing ions at a region of a first side of the component so as to induce sputtering of contaminants present on a second side of the component.

Irradiating a region of the component may comprise directing ions at a region of a first side of the component so as to induce sputtering of contaminants present on a second side of the component.

Irradiating a region of the component may comprise heating the region of the component so as to induce thermomechanical vibrations in the component; and irradiating the region of the component with ions so as to induce sputtering of contaminants present on the component.

The method may comprise: irradiating the component with radiation with a first slit width; and irradiating a second component with radiation with a second slit width. The component and the second component may be the same. Alternatively, the first and second component may be different.

The method may comprise: testing, by irradiating the component with radiation with a first slit width, the structural integrity of the component; reducing the slit width of the radiation from the first slit width to a second slit width; cleaning, by irradiating the component with radiation with the second slit width, the component.

In another example described herein there is a controller configured to control a system of the first example to perform the method of the second example.

In another example described herein there is a component cleaned according to the method of the second example. Advantageously, a component cleaned according to the method disclosed herein may be cleaner. In the example in which the component is a pellicle, the membrane of the pellicle cleaned according to the method disclosed herein may also have a higher tension than otherwise.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 depicts an example cleaning tool for cleaning a component related to a lithographic process;

FIGS. 3A, 3B, 3C and 3D depict alternative example arrangements of a cleaning tool for cleaning a component related to a lithographic process;

FIG. 4 depicts a pellicle;

FIG. 5 is a chart depicting cleaning performance of a cleaning tool for cleaning a component related to a lithographic process;

FIGS. 6A and 6B are charts depicting cleaning performance of a cleaning tool inside and outside of an irradiated region of a component, respectively;

FIG. 7 depicts another example cleaning tool;

FIG. 8 depicts further example components of the cleaning tool of FIG. 7;

FIG. 9A depicts a first schematic diagram of a component related to a lithographic process being cleaned; and

FIG. 9B depicts a second schematic diagram of a component related to a lithographic process being cleaned.

### DETAILED DESCRIPTION

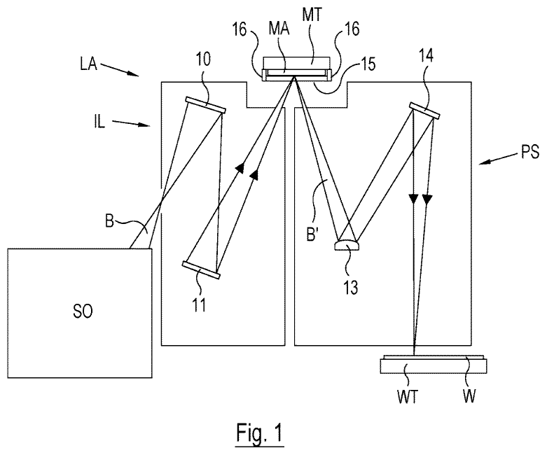

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask, also referred to as a reticle), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

Contaminants (for example, particles or vapour present in the lithographic apparatus LA) may accumulate on the surface of the patterning device MA. The accumulation of contaminants on the patterning device MA may result in defects in the pattern of the patterning device MA, causing defects in the pattern of the patterned EUV radiation beam B′ which consequently causes defects in the pattern produced on the substrate W. Multiple substrates W may be mounted on the substrate table WT at once and exposed sequentially. A single defect (for example, due to the accumulation of contaminants) on the patterning device MA may therefore result in multiple defects in the patterns produced on the substrates W.

To mitigate the accumulation of contaminants on the patterning device MA, the lithographic apparatus LS may be provided with a pellicle 15. The pellicle 15 may be positioned adjacent to, or at a small distance from, the patterning device MA such that contaminants that would otherwise contaminate the patterning device MA (and cause defects in the patterns form by the patterned EUV radiation beam B′) accumulate on the surface of the pellicle 15. For example, in the example lithographic system LA, the pellicle 15 is positioned on the downward facing side of the patterning device MA i.e. the side opposed to the support structure MT. The pellicle 15 may prevent contaminants from accumulating on the patterning device MA and therefore mitigating the associated defects.

The pellicle 15 may comprise a membrane and a border. The membrane may alternatively be referred to as a film and may be substantially transparent to EUV radiation i.e. the EUV radiation beam B, B′ may pass through the pellicle 15 with a relatively low amount of energy from the EUV radiation beam B, B′ being absorbed by the pellicle 15. By way of example only, the pellicle 15 may comprise silicone (Si) or carbon nanotubes. The pellicle 15 may be either open (i.e. the membrane is a mesh and permeable to gases) or closed (i.e. the membrane provided a continuous surface between each edge of the border and is impermeable to gases). The pellicle 15 may further comprise one or more layers of a material with a high emissivity, for example, a metallic layer. A pellicle 15 comprising a metallic layer may maintain a lower temperature (in use in the lithographic system LA) than otherwise. During a manufacturing step, the membrane may be fixed to the border such that the surface of the membrane is held in tension. Alternatively, the membrane and the border may comprise a single homogenous material. The pellicle 15 may be constructed in a different manner or from different materials which may be dependent on or optimised, for example, the wavelength of the radiation beam B, B′ the pellicle 15 is expected to be used with.

The pellicle 15 may be removably mounted to the patterning device MA or the support structure MT. In the example lithographic apparatus LA, the pellicle 15 is removably mounted to the patterning device MA by use of a pellicle frame 16. Removably mounting the pellicle 15 allows for the pellicle 15 to be removed and/or replaced as required.

When the pellicle 15 is fixed in position, the EUV radiation beam B passes through the pellicle 15 prior to being patterned (by the patterning device MA) and the patterned EUV radiation beam B′ passes through the pellicle after patterning (by the patterning device MA).

Through prolonged use, contaminants may accumulate on a surface of the pellicle 15, typically the surface facing away from the patterning device MA. As the pellicle 15 is adjacent to, or at a small distance from, the patterning device MA, (i.e. out of a field plane of the lithographic apparatus LA) contaminants accumulating on the pellicle 15 may be out of focus for the EUV radiation beam B, B′. The same accumulation of contaminants on a pellicle 15 may therefore result in reduced defects in the patterned EUV radiation beam B′ (compared to the defects caused by a similar level of accumulation of contaminants on the patterning device MA). This may lead to reduced (in number and/or size) defects in the patterns produced on the substrate W.

Through further prolonged use, contaminants may further accumulate on a surface of the pellicle 15 and cause intolerable defects in the patterned EUV radiation beam B′ and the patterns produced on the substrate W. Additionally, a pellicle may become contaminated during manufacture and require cleaning prior to an initial use of the pellicle.

Additionally or alternatively, contaminants may accumulate on the surface of other components of the lithographic apparatus LA. For example, contaminants may accumulate on the surface of the substrate W before and/or after the substrate W has been patterned by the radiation beam B′. If the substrate W is contaminated (with contaminants) prior to being patterned, regions on the surface of the substrate W may be obscured by contaminants and not exposed to the patterned EUV radiation beam B′ in the correct manor.

As a further example, contaminants may accumulate on a surface of the patterning device MA (i.e. the reticle). Such accumulation may occur regardless of whether the lithographic apparatus LA has been provided with a pellicle 15. For example, contaminants may accumulate prior to the patterning device MA being mounted in the lithographic apparatus (LA), prior to the pellicle 15 being mounted in the lithographic apparatus LA and/or after the patterning device MA and the pellicle 15 have both been mounted in the lithographic apparatus LA. Contaminants accumulated on the surface of the patterning device may cause defects in the pattern produced on the substrate W in a similar manner as described above.

As a further example, contaminants may accumulate on a surface of the pellicle frame 16. The pellicle frame 16 may transfer contaminants onto a pellicle 15 (or another pellicle after the pellicle 15 has been replaced) thereby causing defects in a similar manner as discussed above.

As a further example, contaminants may accumulate on a surface of a device configured for handling, storing and/or transport reticles and/or pellicles. Such a device may be referred to as a reticle pod. A contaminated reticle pod may contaminate any pellicle handled, stored or transported by the reticle pod thereby causing defects in a similar manner as discussed above.

A lithographic tool is a tool configured to pattern a substrate with radiation. A metrology tool is a tool configured to measure a characteristic of a lithographic apparatus or substrate patterned by a lithographic apparatus. In other words, either lithographic tools or metrology tools may be described as tools relating to a lithographic process. As a further example of detrimental accumulation of contaminants, lithographic tools and/or metrology tools may be contaminated. The contaminants may cause defects in the performance of the (lithographic or metrology) tool and/or contaminate any lithographic apparatus or substrate the tool is used with.

In other words, contaminants may accumulate on surfaces of components related to a lithographic process. The components related to a lithographic process may comprise components of the lithographic apparatus LA, a lithographic tool, a metrology tool and/or a reticle pod. The components related to a lithographic process may comprise a substrate configured to be patterned by a lithographic apparatus or a substrate already patterned by a lithographic apparatus. Example components include a reticle, a pellicle, a reticle clamp and a pellicle frame. While the lithographic apparatus LA described thus far has been described as a using EUV radiation, the lithographic apparatus LA or the lithographic process may use DUV radiation.

In one example, a cleaning tool for cleaning a component related to a lithographic process comprises a heater. During use to clean the component, the heater provides radiation to heat a region of the component so as to cause thermomechanical vibrations in the component. The thermomechanical vibrations in the component dislodge/release contaminants from the surfaces of the component, thereby causing a cleaning effect.

The heater may be a radiation source. The radiation (which heats the region of the component) may be periodic. The heater may take any appropriate form and may be referred to as a component heater. For example, the heater may be a laser and the radiation may be laser light. By way of alternative example, the heater may be a lithographic apparatus where either laser light or generated lithographic radiation (e.g. EUV radiation B, B′ or DUV radiation in a DUV lithographic system), heats the component. The term radiation, as used herein, generally refers to electromagnetic radiation.

The component (i.e. the component related to a lithographic process cleaned by the cleaning tool) may be a component of: the lithographic apparatus LA; a lithographic tool; or a metrology tool. The component may be a substrate configured to be patterned by a lithographic apparatus or a substrate already patterned by a lithographic apparatus. Example components of the lithographic apparatus LA which may be cleaned by the apparatus cleaning tool include a reticle (such as the making device MA), a reticle clamp, a pellicle (such as the pellicle 15) or a pellicle frame. According to an example method of cleaning action (discussed below), any component that sufficiently absorbs the radiation and has a finite coefficient of thermal expansion may be cleaned.

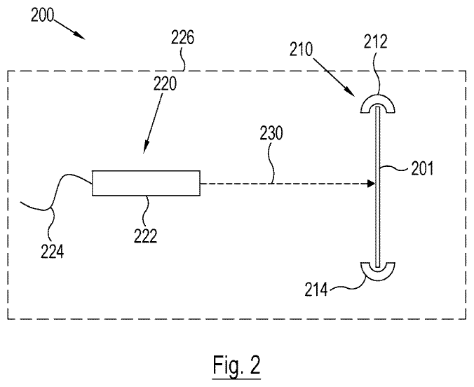

FIG. 2 depicts an example cleaning tool 200 comprising a heater 220. The cleaning tool 200 further comprises a mount 210. The heater 220 may be a laser. A component 201 is removable mounted to the mount 210. The component 201 is heated by radiation 230 provided by the heater 220. The cleaning tool 200 may alternatively be referred to as a cleaning system.

In the example cleaning tool 200, the mount 210 comprises clamps 212, 214. While the cleaning tool 200 is shown as comprising a mount 210, the mount 210 is not an essential feature of the cleaning tool 200. The mount 210 may beneficially hold the component 201 in a fixed position relative to the heater 220 such that the region of the component 201 is consistently heated by the heater 220. In other words, the mount 210 prevents relative movement of the component 201 with respect to the heater 220 thereby causing the heater 220 to heat the intended region of the component 201. The mount 210 may not be necessary for cleaning tools configured to clean larger or fixed components. Additionally or alternatively, other fixing means may be provided. For example, the component 201 may be fixed relative to the heater 220 using other means. As an example, the cleaning tool 200 may comprise a clamp which secures the cleaning tool 200 (and the heater 220) to the component 201 or another structure that is fixed with respect to the component 201. For example, the cleaning tool 200 may be secured to the lithographic apparatus LA allowing the cleaning tool 200 to clean components of the lithographic apparatus LA. Additionally or alternatively, the mount 210 may be configured to allow the component 201 to rest on the mount 210 in a stable manner. For example, the mount 210 may be configured such that the component 201 may be laid on to the mount 210 and held in place by gravity.

As discussed above, the component 201 cleaned by the cleaning tool may be any component related to a lithographic process. In FIG. 2 and the corresponding description, the component 201 is a pellicle. However, it should be understood that the pellicle 201 is an example of any component relating to a lithographic process and the cleaning tool 200 is not limited to cleaning pellicles only. Likewise, in FIG. 2 and the corresponding description, the radiation 230 is pulsed (i.e. provides periodic heating). It should be understood that the periodic aspect of the radiation 230 is exemplary and not an essential feature.

The pellicle 201 may be similar, or identical, to the pellicle 15. The pellicle 201 may have previously been contaminated with contaminants (e.g. particles and/or vapour) and require cleaning. In the text below, the cleaning tool 200, the heater 220 and the mount 210 may be referred to as a pellicle cleaning tool 200, pellicle heater 220 and pellicle mount 210, respectively.

During operation, radiation 230 provides thermal energy to a region of the pellicle 201. By pulsing the radiation 230 that irradiates the pellicle 201 (i.e. by irradiating and then not irradiating the pellicle 201 repeatedly), the pellicle 201 will heat and cool rapidly, causing thermomechanical vibrations to be induced in the pellicle 201 due to the finite co-efficient of thermal expansion. The thermomechanical vibrations provide sufficient energy and momentum to release particles (and possibly other contaminants) from the surfaces of the pellicle 201. The energy and momentum to release particles may alternatively be considered as acceleration of, and forces applied to, the pellicle 201 and the contaminants. For some types of pellicle 201, exposure to a pulse (or pulses) of radiation 230 for too long, may damage the pellicle 201 due to, for example, deformation, oxidation and/or mechanical fatigue. Deformation of the pellicle 201 may alternatively be referred to as wrinkling. In some examples, properties of the radiation 230 (for example, the duration that the (pulsed) radiation 230 irradiates the pellicle 201 for) may be limited to ensure that the pellicle 201 is not damaged. Damage of the pellicle 201 may be repairable or reversible.

As described above, the pellicle heater 220 may be a laser. The laser may comprise a pump source, gain medium and one or more mirrors (not shown). The laser may be a narrow band laser. References to wavelengths (of the radiation 230 provided by the pellicle heater 220) herein may refer to a single wavelength in the example where the pellicle heater 220 is a narrow band laser.

The pellicle heater 220 may comprise a pellicle heater housing 222 and/or may be provided with power by a power supply 224.

The pellicle heater 220 may be pulsed, or otherwise provided with a mechanism of rapidly changing cycling the radiation 230. In the example in which the pellicle heater 220 is a laser, the laser may be a pulsed laser. Experimental results (discussed further below) indicate that a pulse rate of approximately 1 Hz to 1 MHz and an irradiation period of approximately 1 fs to 10 μs may be suitable. For some types of pellicle 201, a pulse rate of 10 kHz and/or an irradiation period of 10,000 ns may be preferable.

Characteristics of the radiation 230 may be tuned to the characteristics the pellicle 201. For example, the radiation 230 may be tuned in space to an eigenmode of the membrane of the pellicle 201 and tuned in time to the eigenfrequency corresponding to the eigenmode. In other words, the radiation 230 may be tuned to beneficially make use of a resonant frequency of a normal mode of the pellicle 201 to improve the cleaning effect.

Properties (e.g. the power, wavelength and/or frequency) of the radiation 230 may be selected to ensure the pellicle 201 being cleaned absorbs enough energy to induce the thermomechanical vibrations in the pellicle 201 to cause a cleaning effect and not too much energy to cause damage to the pellicle 201. For example, the properties of the radiation 230 may be selected to ensure the pellicle 201 is heated by less than 1000 K per pulse of radiation. By way of example, it is known that some pellicles absorb a large fraction of energy provided in the IR spectrum (300 GHz to 4300 THz). Therefore, for such pellicles it may be preferable for the radiation 230 to have a wavelength corresponding to the IR spectrum to maximise the absorption of the radiation 230 by the pellicle. Alternatively, wavelengths corresponding to the visible spectrum (400 THz to 790 THz) or the UV spectrum (750 THz to 30 PHz) may be beneficial for irradiating pellicles 201 constructed using other means. More generally, any wavelength of radiation 230 may be used provided the radiation is sufficiently absorbed by the component 201 to cause a cleaning effect. For example, wavelengths of up to 1 mm may be used.

Additionally or alternatively, the properties of the radiation 230 may be selected to increase or optimise an acceleration of the thermomechanical vibrations induced in the pellicle 201. In other words, the induced thermomechanical vibrations may be characterised by one or more mechanical waves travelling through the pellicle 201 and the properties of the radiation 230 may be selected to increase or optimise an acceleration (i.e. acceleration amplitude) of the one or more mechanical waves. Beneficially, increasing the acceleration may improve the cleaning effect. For example, a slit width (in one or more dimensions) of the radiation 230 may be decreased to decrease a wavelength of the one or more mechanical waves. Given that a speed of the one or more mechanical waves in the component 201 is constant, decreasing the wavelength may increase the frequency and thus increase the acceleration of the one or more mechanical waves. Increasing the acceleration in this way may decrease an in-pulse intensity and/or a decrease time-averaged intensity of the radiation 230.

Higher power radiation 230 (e.g., 200 W) may provide more energy, for example, for a pellicle 201 that has a low absorption for the wavelengths of radiation 230 used. As a counter example, for a pellicle 201 that absorbs a large fraction of energy from the radiation 230 and a lower power of radiation 230 may be sufficient. For example, for a pellicle 201 that absorbs a large fraction of radiation 230 from the IR spectrum, irradiating the pellicle 201 with IR radiation 230 with a power of 1 mW may be sufficient.

Likewise, the power of the radiation 230 may depend on the pulse rate and pulse length. For example, for lower pulse rates and/or shorter pulse lengths, the radiation 230 will irradiate the pellicle 201 for less time than otherwise. Therefore, the radiation 230 may require a higher power if lower pulse rates and/or shorter pulse lengths are used (and vice versa). Lower pulse rates and/or shorter pulse lengths may cause thermomechanical vibrations with a higher frequency (than otherwise) thereby providing an improved cleaning effect (than otherwise). As an alternative, the radiation may continuous (i.e. from a continuous laser) or a single pulse (i.e. a single pulse of a pulsed laser). In other words, the radiation 230 may heat the region of the pellicle 201 a single time.

The radiation 230 may not have a single, consistent pulse rate and/or length. For example, the pulse rate may be a first value and changed (gradually or instantaneously) to a second value. Alternative patterns of pulsing may be used.

The radiation 230 may be a beam and may be provided with a shape or profile. For example, the region of the pellicle 201 irradiated by the radiation 230 may have a shape similar to a circle, a square, a rectangle, a crescent or otherwise. The power and/or the shape of the beam of radiation 230 may be chosen to correspond to the bulk wave propagation speed of the material of the pellicle 201 to provide an optimum cleaning effect. As an example, the radiation 230 may have a circular profile with a radius of less than 1 mm. As an alternative example, radiation 230 may have a profile of a narrow rectangle (i.e. a ‘slit’) with a dimension of less than 1 mm. Such a slit may be optimum for some materials. As an alternative example, a beam with a profile with of a meniscus (i.e. a crescent shape) may be optimum for other materials.

The radiation 230 may be incident upon the pellicle 201 at any angle. To minimise reflection of the radiation 230 off the pellicle 201 (and therefore achieve higher absorption), an angle of incidence (i.e. the angle between the radiation 230 and a line extending perpendicular from the surface of the pellicle 201) of approximately 0° may be used. Alternatively, the angle of incidence may be selected to obtain a desired absorption of radiation or with other considerations in mind, for example, the layout of the pellicle cleaning tool 200.

Experimental results indicate that the region of the pellicle 201 outside the irradiated region (i.e. the region irradiated by the radiation 230) may experience more cleaning than the region irradiated. In other words, more contaminants may be removed from the pellicle 201 when a region other than the region containing the contaminants is irradiated than when the region containing the contaminants is irradiated. Therefore, the tool 200 may be provided with means for adjusting the region irradiated (by radiation 230) on the pellicle 201. For example, the pellicle heater 220 may comprise an actuator to change the position or angle of the pellicle heater 220 which results in irradiating a different region of the pellicle 201. Additionally or alternatively, the pellicle mount 210 (or any additional or alternative fixing means) may comprise an actuator to change the position of the pellicle 201 (for example, by raising or lowering the clamps 212, 214) to change the region of the pellicle 201 that is irradiated. Additionally, or alternatively, one or more beam-positioning devices (such as mirrors, lenses) may be provided between the pellicle heater 220 and the mount 210 to direct the radiation 230.

The radiation 230 may not be entirely absorbed by the pellicle 201. The pellicle cleaning tool 200 may be provided with means for the safe dispersal or absorption of the radiation 230, for example, with a beam dump (not shown). The beam dump may be provided in a position such that the radiation 230 is incident upon the beam dump after irradiating the pellicle 201.

One or more optics, for example, mirrors, may be used to divert the radiation 230 prior to, or after, irradiating the pellicle 201. For example, mirrors may direct the radiation 230 to a beam dump after irradiating the pellicle 201.

The pellicle cleaning tool 200 may comprise metrology for measuring the intensity of the radiation 230 prior to, or after, irradiating the pellicle 201. For example, the pellicle cleaning tool 200 may measure the intensity of the radiation 230 prior to and after irradiating the pellicle 201 and thereby calculate the dose of the radiation 230 the pellicle 201 has received. The intensity of the radiation 230 prior to irradiating the pellicle 201 may be estimated based on known, or measured, characteristics of the pellicle heater 220. The metrology for measuring the intensity of the radiation 230 after irradiating the pellicle 201 may be provided in, or with, a beam dump.

The pellicle mount 210 may comprise fittings to allow the pellicle 201 to be removably fixed in a position to be irradiated by the pellicle heater 220. For example, the pellicle mount 210 may comprise one or more clamps 212, 214. The one or more clamps 212, 214 may be provided in locations to fix to opposing sides of the pellicle 201, for example the upper and lower sides of the pellicle 201. Advantageously, the tolerance relating to the position of the pellicle 201 within the pellicle cleaning tool 201 may be more relaxed than the tolerance of the position of the pellicle 15 in the lithographic apparatus LA. Alternatively, the pellicle mount 210 may use substantially the same hardware and methods of fixation as those known to the skilled person and provided, for example, in the pellicle frame 16.

The pellicle 201 may be removably fixed to the pellicle mount 210 such that a side of the pellicle 201 is irradiated by the radiation 230. The side of the pellicle 201 irradiated by the radiation 230 may be either side of the membrane (or a side of a metallic coating on the membrane). The side of the membrane irradiated by the pellicle heater 230 may be the side (of the pellicle 201) upon which the contaminants have accumulated or, alternatively, may be the side opposing the side upon which the contaminants have accumulated.

The pellicle cleaning tool 200 may comprise a housing 226 in which the pellicle mount 210 and pellicle heater 220 are provided. The housing 226 may provide a sealed environment for the pellicle cleaning tool 200. The housing 226 is shown in dashed-line to indicate that the housing may not be present in all example implementations. That is, the tool 200 may be housed within another system and not have its own dedicated housing.

The pellicle cleaning tool 200 may comprise components to provide a low ambient pressure in the housing 226, for example, a vacuum pump (not shown). A low ambient pressure, for example, an ultra-high vacuum (UHC) may beneficial contribute to the removal of contaminants from the pellicle 201 and (after removal of contaminants from the pellicle 201) contribute to the removal of contaminants from the region near to the pellicle 201. Alternatively or additionally, the pellicle cleaning tool 200 may comprise components (not shown) to provide an internal environment (i.e. internal to the housing) enriched by a particular gas, for example, nitrogen or hydrogen. Enriching the internal environment with nitrogen may help prevent damage (for example, due to oxidation) of the pellicle 201 and/or increase the rate at which the pellicle 201 cools following heating from the radiation 230 (which may increase the amplitude of the thermomechanical vibrations produced).

The housing 226 may comprise a hatch (not shown), or otherwise, that may be opened to provide access to the pellicle cleaning tool 200 allowing, for example, the mounting (or removal) of a pellicle 201 to (or from) the pellicle mount 210. Alternatively, or additionally, the housing 226 may comprise a panel that may be removably fixed to the housing to provide access. When closed, the hatch (or panel) may provide an airtight (i.e. vacuum proof) seal within the housing 226.

The housing 226 may comprise a chamber with two hatches (i.e. a load lock chamber), to allow a pellicle 201 to be inserted or removed from the housing without compromising the internal environment of the housing. The chamber may define (and seal) an internal environment separate to the internal environment of the housing 226 and to the external environment. The first hatch (of the two hatches) may open to the external atmosphere and the second hatch may open to the internal environment of the housing. The load lock may prevent both of the two hatches from being opened at the same time. To load a pellicle 201, the first hatch may be opened and the pellicle 201 may be placed in the chamber. The first hatch may be closed and the internal environment of the chamber may be equalized (or approximately equalized) to the internal environment of the housing 226. For example, the ambient pressure may be reduced to close to that within the housing 226 and/or the nitrogen concentration may be increased to close to the nitrogen concentration in the internal environment of the housing 226. After equalization, the second hatch may be opened and the pellicle 201 may be transferred from the chamber to the pellicle mount 210. A reverse process may be followed for removing the pellicle 201 from the housing 226.

The housing 226 may be provided with a system for removing contaminants from the internal environment once the contaminants have been released from the pellicle 201. For example, a gas inlet may direct the contaminants towards an exhaust for removal from the internal environment of the housing 226.

The housing 226 may be provided with components for assisting with the insertion or removal (from the housing or load lock chamber) or mounting or dismounting (on or from the pellicle mount 210) of the pellicle 201. For example, the housing 226 may be provided with a robotic arm (not shown). Alternatively or additionally, the pellicle mount 210 may itself be movable such that the pellicle mount 210 may be moved from a position in the housing to a position in the load lock chamber. For example, the pellicle mount 210 may be provided on a rail and a control system to move the pellicle mount 210 along the rail from a first position inside the housing 206 (where the pellicle 201 may be irradiated by the radiation 230) to a second position inside a load lock chamber (where the pellicle 201 may be removed from the pellicle mount 210 when the first hatch of the load lock chamber is open).

The pellicle cleaning tool 200 may comprise components for measuring the contamination of the pellicle 201, for example, a camera or metrology comprising a laser (in the example in which the pellicle heater 220 is a laser, the pellicle heating laser or an additional laser). The components for measuring the contamination of the pellicle 201 may measure the contamination one or more times. For example, the contamination of the pellicle 201 may be measured once prior to cleaning to indicate whether cleaning is needed or how long the cleaning should last (i.e. how long the radiation 230 should irradiate the pellicle 201). Additionally or alternatively, the contamination of the pellicle 201 may be measured continuously (or at regular intervals) to provide an indication of whether the cleaning of the pellicle 201 should continue. The measure of contamination of the pellicle 201 may be a measure of the contamination across different regions of the pellicle 201 and provide an indication of where the radiation 230 should irradiate the pellicle 201.

The lithographic apparatus LA may comprise the pellicle cleaning tool 200 to allow in-situ cleaning. Other tools or components used in lithography, for example, metrology tools, may comprise the pellicle cleaning tool 200.

The pellicle cleaning tool 200 may be used during the manufacture of a pellicle 201, for example, prior to or after fixing the membrane to the border. The radiation 230 may irradiate the membrane of the pellicle 201. In addition to cleaning the pellicle, the tool 200 may beneficially increase the surface tension of the membrane.

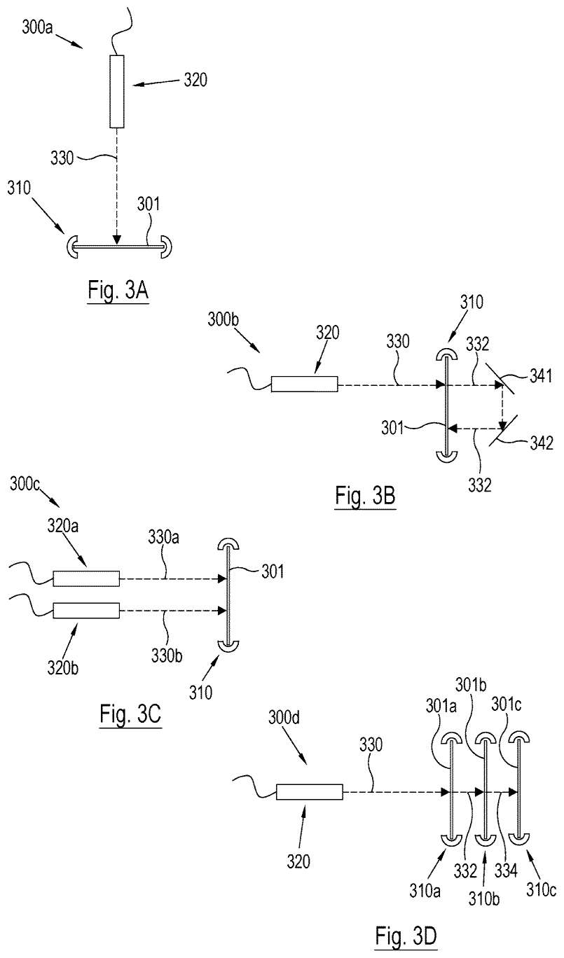

FIGS. 3A-D show further examples of pellicle cleaning tools 300a, 300b, 300c, 300d, respectively, each of which comprises substantially the same components as the pellicle cleaning tool 200 (i.e. radiation 330 is provided by a pellicle heater 320 and a pellicle 301 is removably fixed to a pellicle mount 310 and irradiated by the radiation 330). Similar or corresponding elements are given similar or corresponding reference numerals in the Figures described herein.

FIG. 3A shows pellicle cleaning tool 300a comprising a pellicle 301 held in a pellicle mount 310 and aligned in a substantially horizontal position. Radiation 330 is irradiated from a pellicle heater 320 in a position vertically above the pellicle 301 (with respect to gravity) and heats the pellicle 301. The pellicle 301 may be arranged such that a side of the pellicle 301 more heavily contaminated or a side of the pellicle 301 expected to be more heavily contaminated (i.e. the side of the pellicle 301 that faces away from the patterning device MA when in place in a lithographic apparatus LA) is facing downward (i.e. away from the incident radiation 330). Advantageously, gravity may help release contaminants from the pellicle 301 and/or remove released contaminants from the region proximal to the pellicle 301.

FIG. 3B shows a pellicle cleaning tool 300b, having substantially the same components as the pellicle cleaning tool 200, and further comprising one or more mirrors 341, 342. A proportion of the radiation 330 irradiating the pellicle 301 is not absorbed by the pellicle 301 and, after passing through the pellicle 301, the attenuated radiation 332 propagates away the pellicle 301. The one or more mirrors 341, 342 reflect and redirect the attenuated radiation 332 to re-irradiate the pellicle 301. The attenuated radiation 332 may irradiate the pellicle 301 on the face of the pellicle 301 opposed to the face irradiated by the radiation 330. The attenuated radiation 332 may irradiate the pellicle 301 in a region opposing the region irradiated by the radiation 330. Alternatively, the attenuated radiation 332 may irradiate the pellicle 301 in a region different to the region opposing the region irradiated by the radiation 330. Advantageously the one or mirrors 341, 342 may allow the pellicle 301 to be irradiated multiple times by a single pellicle heater 320 (at a single region or multiple regions). Accordingly, this may increase the energy absorbed by the pellicle 301 and increase the frequency or the amplitude of the induced thermomechanical vibrations.

FIG. 3C shows a pellicle cleaning tool 300c comprising two pellicle heaters 320a, 320b. The pellicle heaters 320a, 320b provide radiation 330a, 330b which irradiate the pellicle 301. The radiation 330a, 330b irradiates the pellicle 301 at two points, or alternatively, at a single point. While (in the example of the pellicle cleaning tool 300c) the radiation 330a, 330b is provided by the pellicle heaters 320a, 320b, it is to be understood that two or more beams of radiation 330a, 330b may be provided by use of beam splitting optics and a single pellicle heater.

FIG. 3D shows a pellicle cleaning tool 300d comprising a pellicle heater 320, a number of pellicle mounts 310a, 310b, 310c (collectively referred to as 310) and a number of pellicles 301a, 301b, 301c (collectively referred to as 301). The pellicle heater 320 provides radiation 330 which irradiates the pellicle 301a. A proportion of the radiation 330 irradiating the pellicle 301a is not absorbed by the pellicle 301a and, after passing through the pellicle 301a, the attenuated radiation 332 irradiates the pellicle 302a. A proportion of the attenuated radiation 332 is not absorbed by the pellicle 301b and, after passing through the pellicle 301b, the second attenuated radiation 334 irradiates the pellicle 301c. In this way, multiple pellicles 301 may be cleaned by use of a single pellicle heater 320. The multiple pellicles 301 may each be of a different type (i.e. constructed from different materials) such that wavelengths of radiation 330 preferably absorbed by the first irradiated pellicle 301a are different from the wavelength of radiation 332, 334 preferably absorbed by the other pellicles 301b, 301c. The pellicle mounts 310 may be provided with a mechanism to allow the pellicle mounts 310 to move position and change the order in which the pellicles 301 (held in the pellicle mounts 310) are irradiated.

As will be clear to the skilled person, any combinations of the example pellicle cleaning tools 330a, 300b, 300c, 300d may be considered. For example, a single pellicle 301 may be mounted in a pellicle mount 310 such that the pellicle 301 is substantially aligned horizontally and the pellicle may be irradiated by radiation 330 from multiple pellicle heaters 320 (i.e. the examples pellicle cleaning tools 300a, 300c may be combined). Further, mirrors 341, 342 may be provide to reflect attenuated radiation 332 and irradiate the pellicle 301 on a second side.

Referring again to FIG. 2, the method of use of the pellicle cleaning tool 200 may (in examples in which the cleaning tool 200 comprises a pellicle mount 210) comprise mounting the pellicle 201 in the pellicle mount 210.

As noted above, lithographic apparatus (such as the lithographic apparatus LA) may comprise the pellicle cleaning tool 200. In such a lithographic apparatus, the pellicle 201 may already be in a fixed position (for example, fixed using a pellicle frame such as the pellicle frame 16 and not need fixing to the pellicle mount 210).

The method of use of the pellicle cleaning tool 200 comprises heating the pellicle 201 with radiation 220 from the pellicle heater 230 to induce thermomechanical vibrations. In the example where the pellicle heater 230 is a laser, the thermomechanical vibrations are induced by irradiating the pellicle 201 with laser light. The pellicle 201 may be heated periodically i.e. the pellicle heater may be pulsed. The thermomechanical vibrations may provide sufficient energy and momentum to release particles from the surfaces of the pellicle 201, in other words, the pellicle 201 may be cleaned.

As noted above, the pellicle cleaning tool 200 may comprise housing 226 (and, optionally, a load lock) in which a low ambient pressure is provided. Prior to irradiation by the pellicle heater 220, the pellicle 201 may be removably fixed within the housing 226 (or the load lock) either in the pellicle clamp 210 or otherwise (for example, in a temporary location in the load lock). The ambient pressure within the housing 226 (or the load lock) may then be reduced. Reducing the ambient pressure may also remove contaminants from the pellicle, in addition to the cleaning effect cause by the induced thermomechanical vibrations.

The cleaning effect may be greater in a region of the pellicle 201 near to the irradiated region (i.e. the region irradiated by the radiation 230). In other words, a greater proportion of the contaminants may be removed from a surface of the pellicle 201 in a region that is not irradiated. Therefore, the radiation 230 may irradiate different regions of the pellicle 201 either sequentially (by movement of the pellicle heater 220, pellicle mount 210 or use other optics) or simultaneously (by use of two or more pellicle heaters 220 or optics). The amplitude of the thermomechanical vibrations may be smaller (and so the cleaning effect may diminish) in regions of the pellicle further away from the irradiated region.

The method may further comprise irradiating additional regions of the pellicle 201. For example, the position of the pellicle 201 in relation to the pellicle heater 220 may be changed and/or the pellicle heater 220 may be adjusted so the radiation 230 irradiates the pellicle 201 in a different region.

The method of use of the pellicle cleaning tool 200 may further comprise irradiating the pellicle 201 with multiple wavelengths of radiation 230 (either simultaneous or sequentially). For example, the pellicle 201 may first be irradiated with a first wavelength of radiation 230 to remove a first type of contamination and the pellicle 201 may then be irradiated with a second wavelength of radiation 230 to remove a second type of contamination. The multiple wavelengths of radiation 230 may be provided by adjusting a property of a single pellicle heater 220, or alternatively, by providing the pellicle cleaning tool 200 with multiple pellicle heaters 220, each pellicle heater 220 providing a different wavelength of radiation 230.

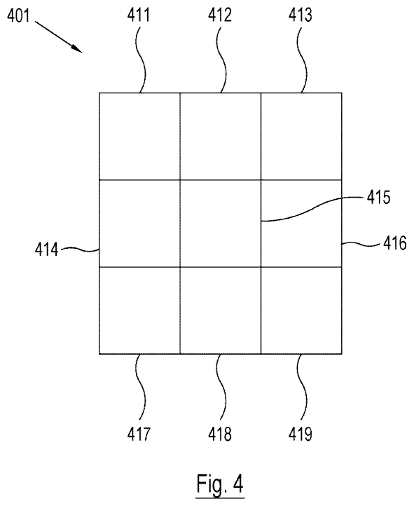

FIG. 4 depicts an example pellicle 401 on which notional regions 411-419 are depicted. The regions 411-419 are simply representative and may not be marked on the surface of the pellicle 401 itself. The pellicle 401 may be the pellicle 201 that is to be cleaned by the pellicle cleaning tool 200. For the purposes of illustration, we will consider that prior to cleaning, the pellicle 401 has been contaminated with a uniform level of contamination across each of the regions 411-419.

First, the centre region 415 of the pellicle 401 may be irradiated (by the radiation 230). The radiation 230 may induce first thermomechanical vibrations. The first thermomechanical vibrations may provide a cleaning effect. The cleaning effect in the irradiated region (i.e. the centre region 415) may be less than the cleaning effect of the other regions 411-419. Subsequently (or simultaneously), a second region, for example, the region 411, may be irradiated to induce second thermomechanical vibrations. The second thermomechanical vibrations may provide an additional cleaning effect. For example, the second thermomechanical vibrations may cause greater cleaning of the centre region 415 than caused by the first thermomechanical vibrations.

Not all regions of the pellicle 401 may be irradiated (by the radiation 230). For example, the region 411 may first be irradiated. The pellicle heater 220 may then be moved to irradiate the regions 413, 417 and 419 in turn. In this way, each region of the pellicle 401 is cleaned by thermomechanical vibrations with some regions (for example, the central region 415 or an edge region 414) cleaned by thermomechanical vibrations arising from several irradiated regions. It will be appreciated, however, that the number of regions irradiated, and the order of those irradiations, may vary depending upon the particular application. In examples in which each of the irradiated regions are irradiated in turn by the same heater, the radiation and/or the heater may be described as scanning across the pellicle 401.

The pellicle cleaning tool 200 and method of pellicle cleaning may be calibrated (i.e. the properties of the radiation 230 or another aspect of the pellicle cleaning tool 200 may be optimised) for a particular type of pellicle 201 (or component or type of component). For example, the wavelength/frequency, the frequency of pulses, the length of time of irradiation of each pulse and/or the shape/profile of the beam of radiation 230 may be optimised. The calibration may also provide a minimum length of time needed for the cleaning effect (from the pellicle cleaning tool 200) to remove contaminants or a maximum length of time (or temperature), after (or above) which the pellicle 201 may be damaged.

Calibration may use experimental data. For example, multiple pellicles may be contaminated. The contamination may be to similar levels and may use one or more artificial contaminants. Example artificial contaminants include zirconium diboride (ZrB₂) or silicon dioxide (SiO₂). Two or more artificial contaminants may be used to contaminate each pellicle 201 to provide both conducting and non-conducting contamination. The contaminated pellicles may be cleaned using the pellicle cleaning tool 200. One or more properties of the pellicle cleaning tool 200, for example, the frequency of the radiation 230 may be varied when each one of the contaminated pellicles is cleaned. The cleaning effect provided by the pellicle cleaning tool 200 may be measured by comparing the contamination of the contaminated pellicles before and after cleaning and as a function of the varied property.

Calibration may comprise irradiating a pellicle 201 with radiation 230 until the wrinkling occurs. For some pellicles, it has been determined that a minimum length of time is 20s and a maximum length of time is 1 hour or more.

Experimental data collected during calibration may be used as an input to a predictive model. The predictive model may be used to calibrate the pellicle cleaning tool 200 for cleaning a pellicle 201 similarly to one or more pellicles used to collect of the experimental data. Alternatively, the predictive model may be used to calibrate the pellicle cleaning tool 200 for cleaning a pellicle 201 even if the pellicle 201 is not similar to any of the pellicles used in the collection of experimental data. In other words, the experimental data may be used to extrapolate and predict the optimum properties of the pellicle cleaning tool 200 for a pellicle 201 (or type of pellicle 201) which has not been cleaned previously.

Table 1 shows an example set of properties tested in a calibration of the pellicle cleaning tool 200. The pellicle cleaning tool 200 used to test the conditions shown in table 1 comprised an infrared (IR) laser with a maximum power of 200 W.

TABLE 1
An example set of conditions tested in the calibration of the pellicle cleaning tool

| Test number | 1 | | 2 | | 3 | | 4 | |
|---|---|---|---|---|---|---|---|---|
| Atmosphere | 10⁻⁶ mbar | | 10⁻⁶ mbar | | 10⁻⁶ mbar | | 3 Pa H₂ | |
| | vacuum | | vacuum | | vacuum | | | |
| Pulse rate | 50 | kHz | 10 | kHz | 10 | kHz | 50 | kHz |
| Power | 10% | | 10% | | 10% | | 10% | |
| Pulse length | 2,500 | ns | 5,000 | ns | 10,000 | ns | 3,000 | ns |
| Duration | 5 | minutes | 20 | seconds | 5 | minutes | 5 | minutes |

Table 2 shows the cleaning results corresponding to the conditions shown in table 1. The pellicles 201 tested in these results were constructed from a metal silicide film and were contaminated with artificial contaminant (ZrB₂) prior to the testing. ‘PRD overall’ indicates the percentage and number of all production contaminants greater than 1 μm in diameter removed in all regions of the pellicle 201. PRD and production contaminants refers to contamination introduced in the pellicle production process, in other words, contaminants that were not introduced artificially. ‘ZrB₂ overall,’ ‘ZrB₂ non-exposed and ‘ZrB₂ exposed’ indicates the percentage and number of artificial contaminants greater than 1 μm in diameter removed in all regions, the non-irradiated regions and the irradiated region of the pellicle 201, respectively. Not all contaminants are spherical. For a non-spherical contaminant, the diameter (as used here) refers to the diameter of a sphere that would have the same volume or cross-sectional area as the non-spherical contaminant.

TABLE 2
An example set of conditions tested in the
calibration of the pellicle cleaning tool

| Test number | 1 | 2 | 3 | 4 |
|---|---|---|---|---|
| PRD overall | 94.0% | 37.5% | 96.4% | 85.4% |
| | (204/217) | (3/8) | (54/56) | (35/41) |
| ZrB₂ overall | 67.6% | 66.4% | 90.1% | 68.1% |
| | (248/367) | (245/369) | (257/283) | (192/282) |
| ZrB₂ non- | 79.3% | 68.4% | 93.6% | 74.9% |
| exposed | (207/261) | (175/256) | (190/203) | (149/199) |
| ZrB₂ | 38.1% | 61.9% | 83.8% | 51.8% |
| exposed | (40/105) | (70/113) | (67/80) | (43/83) |

Table 2 indicates that the parameters used in test number 3 were the parameters that provided the best cleaning out of the parameters tested.

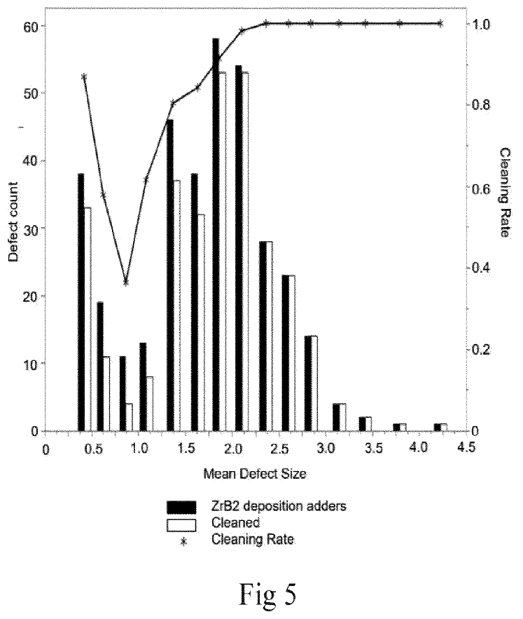

FIG. 5 shows an example plot indicating the number of contaminants present on the pellicle 201 used in test 3 before and after cleaning with the pellicle cleaning tool 200, plotted as a function of the size of the contaminant. The cleaning rate (i.e. the proportion of contaminants removed by cleaning) is also shown. FIG. 5 shows that cleaning is particularly effective for larger contaminants.

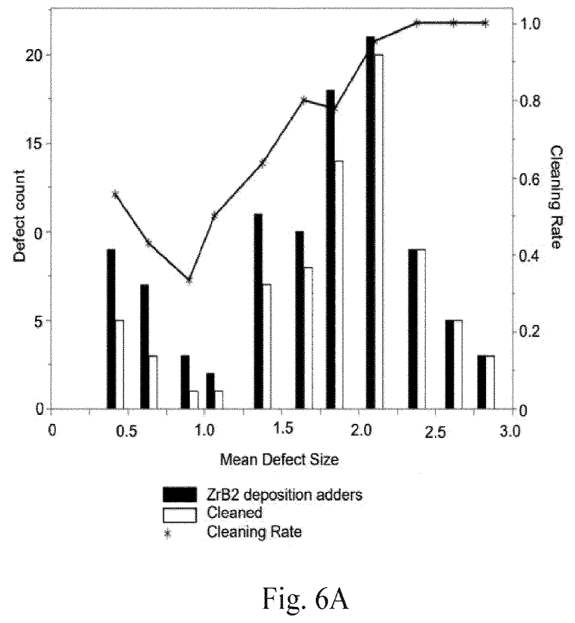

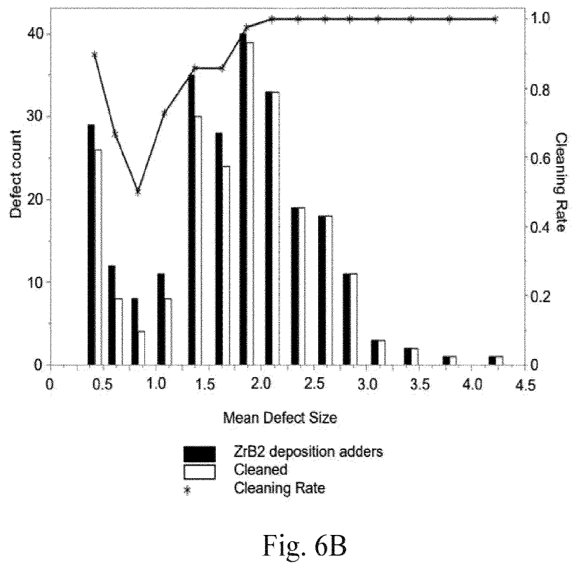

FIG. 6A shows a plot (likewise to the plot shown in FIG. 5) limited to data from the irradiated region.

FIG. 6B shows a plot (likewise to the plot shown in FIG. 5) limited to data from outside of the irradiated region.

Together FIGS. 6A and 6B show how the cleaning effect of the pellicle cleaning tool 200 is more effective outside of the irradiated region.

The pellicle cleaning tool 200 (and possibly other apparatus comprising the pellicle cleaning tool) may be controlled by a computer system. For example, the computer system may monitor the contamination of the pellicle 16 during use in the lithographic apparatus LA. The computer system may identify when contamination of the pellicle 16 reaches unacceptable levels and transfer the pellicle 16 into the pellicle cleaning tool 200. As a further example, the computer may monitor the contamination of the pellicle 201 in the pellicle cleaning tool 200 and adjust the pellicle heater 220 accordingly. The pellicle 201 may have first and second contaminated regions. The computer may identify the two contaminated regions and control the pellicle cleaning tool 200 to irradiate a region of the pellicle 201 near the first contaminated regions. The computer may monitor the contamination levels in the first contaminated region, and once the computer determines the first region is cleaned, adjust the pellicle cleaning tool 200 such a region near the second contaminated region of the pellicle 201 is irradiated by radiation 230. The pellicle cleaning tool 200 may then continue irradiating the region near the second contaminated region of the pellicle 201 until the computer determines the second region is cleaned.

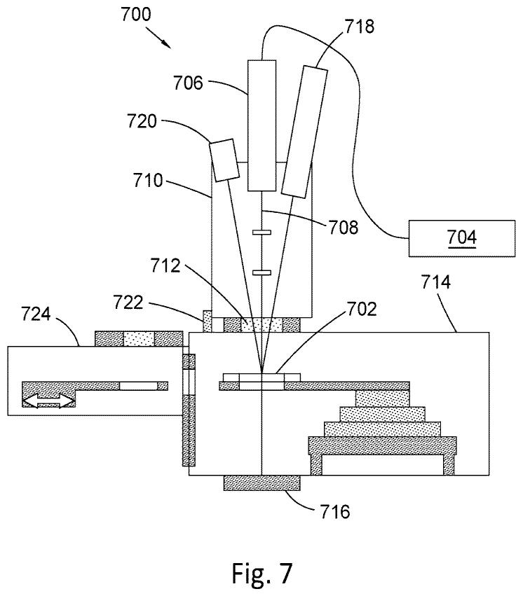

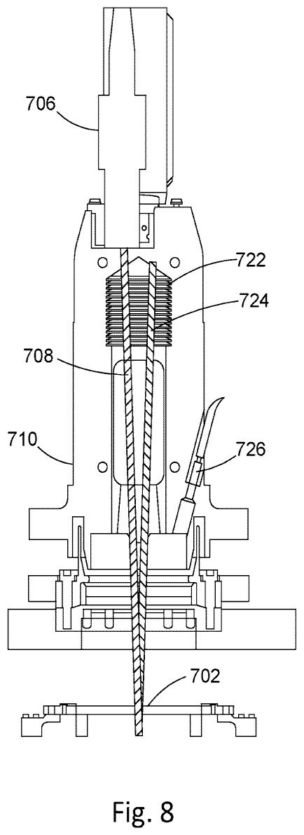

FIGS. 7 and 8 provide a schematic depiction of an example arrangement 700 for cleaning a pellicle 702 in accordance with the principles and techniques described above. As best seen in FIG. 7, the arrangement 700 includes a laser 704 that provides a laser beam to a laser collimator 706. The laser collimator 706 provides a collimated laser beam 708 to a housing 710. The housing 710 may include optical components to further condition the laser beam 708 before it is incident on the pellicle 702. The housing 710 may additionally house one or more others of the components of the arrangement 700 described below. The laser beam 708 passes through a viewport 712 that separates the optics box 710 from a vessel 714 housing the pellicle 702. The vessel 714 may be a vacuum vessel. The viewport 712 may be mounted to the vessel 714 and may be mounted using any appropriate means. For example, the viewport 712 may be mounted to the vessel 714 using bolts. Advantageously, existing vessels 714 in operation may already comprise suitable threaded holes for mounting the viewport 712, making the arrangement 700 suitable for retrofitting to existing tools and apparatuses. The housing 710 may be mounted to the viewport, again using any appropriate means. The housing 710 may be separably mounted to the viewport 712.

Portions of the laser beam 708 that pass through the pellicle 702 may be incident on a beam dump 716. A thermal radiation sensor 718, which may be, for example, a pyrometer is arranged to detect thermal radiation emitted from the pellicle 702. The detection of thermal radiation using the thermal radiation sensor 718 may allow for process control. For example, the power, duration, frequency, etc. of laser radiation provided by the system may be adjusted in response to thermal radiation emitted from the pellicle 702. An optical sensor 720 (for example a camera) is configured to image the surface of the pellicle 702 on which the laser beam 708 is to enable alignment of the thermal sensor 718 and the laser beam 708.

A laser interlock safety mechanism 722 may be provided to automatically shut off the laser beam 708, for example during swapping of the pellicle using a load lock 724.

FIG. 8 depicts example components from the arrangement 700 in more schematic detail. From FIG. 8 it can be seen that a second beam dump 722 is arranged to receive a reflected portion 724 of the laser beam 708. The second beam dump 722 may be contained within the housing 710.

An illuminator 726 (for example one or more LEDs) may be provided to illuminate the pellicle 702 for the optical sensor 720 (not visible in FIG. 8).

As discussed above, components (other than a pellicle) related to a lithographic process may be cleaned by a cleaning tool. Another component (i.e. a component other than the component to be cleaned) may be provided with a cleaning tool allow cleaning of components. As an example, reticle backside inspection tools (i.e. tools for inspecting a backside of patterning devices, such as the patterning device MA) may be provided with a cleaning tool to clean the patterning devices. Additionally or alternatively, cleaning tools may be provided in devices for handling the patterning device MA.

As a further example, a cleaning tool may be provided in reticle exchange devices (i.e. devices for handling patterning devices) and may allow for cleaning of the patterning device MA and/or a portion of the support structure MT.

As a further example, a cleaning tool may be provided in wafer handling tools and may allow for cleaning of the wafer (i.e. the substrate W).

As a further example, a cleaning tool may be integrated with the lithographic apparatus LA to allow for cleaning of components within the lithographic apparatus LA. For example, the lithographic apparatus LA may be provided with one or more members for controlling the region of the substrate W that is exposed to the EUV radiation beam B. Such members may be cleaned by the cleaning tool. Additionally or alternatively, a gas outlet may direct a gas across the surface of the reticle and/or the pellicle to prevent the accumulation of contaminants. Such gas outlets may be cleaned by the cleaning tool.

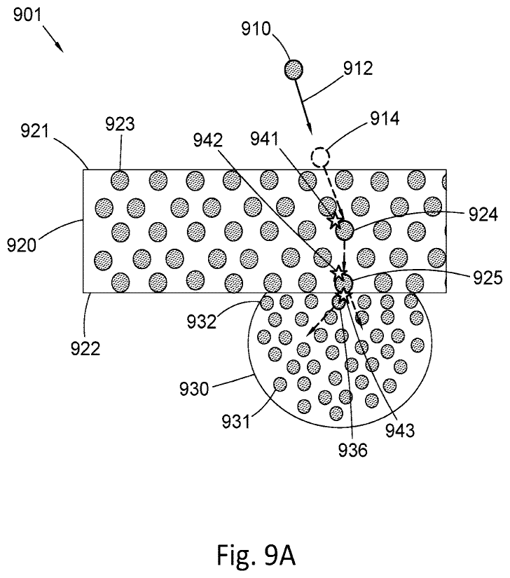

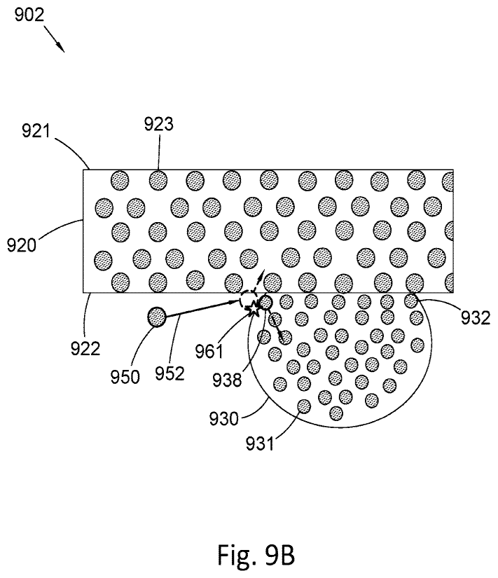

Referring again to FIG. 2, as an additional or alternative to the heater 220, the cleaning system 200 may comprise an ion source. The ion source may provide a cleaning effect referred to as ion beam sputtering and as described below in relation to FIGS. 9A and 9B. The cleaning effect provided by the ion source may be carried out as an alternative to the cleaning effect provided by the heater 220. Alternatively, the cleaning effect provided by the ion source may be carried out in addition to the cleaning effect provided by the heater 220. In examples in which the heater 220 and the ion source are used to provide a cleaning effect, the heater 220 and the ion source may be used in any order. For example, the ion source may be used (to clean the component 201) first and the heater 220 may be used second. The ion beam sputtering may reduce the strength of binding forces binding contaminants to the component 201, thereby increasing the effect of any subsequent cleaning (e.g. cleaning provided by the heater 220). As a further advantage, by using a combination of cleaning techniques (e.g. heating to cause thermomechanical vibrations and radiation with ions to induce sputtering) inadvertent damage caused by a cleaning technique may be reduced and/or avoided entirely. For example, pellicles may be damaged by thermomechanical vibrations (caused by heating as described above). By first reducing binding forces (binding contaminants to a pellicle) using ion beam sputtering, the effect of subsequent thermomechanical vibrations may be improved. Accordingly, less heating may be required to achieve a given cleaning effect and the pellicle may be less damaged (or less likely to be damaged) than when cleaned using heating alone.

FIG. 9A depicts a first schematic diagram of a component related to a lithographic process being cleaned. FIG. 9A depicts a system 901 comprising a component related to a lithographic process 910 which has been contaminated by a contaminant 930. An ion 910 is incident on the component 920.

The ion 910 may be an ion of a noble gas element. Beneficially, ions of noble gas elements may reduce (or avoid entirely) any chemical reactions between the ion 910 and the component 920. For example, the ion 910 may be a positive Argon ion i.e. an Argon atom that has ‘lost’ one or more electrons due to ionisation. Alternatively, the ion 910 may be a positive Helium ion or a positive Neon ion. Advantageously, a positive Helium ion or a positive Neon ion may have a smaller atomic diameter (or radius) compared to a positive Argon ion and the probability of lateral scattering is reduced. In other words, detrimental damage (to the component 920) may be more controlled and contained and an implantation risk may be reduced through use of a positive Helium ion or a positive Neon ion compared to use of other ions. The ion 910 may be one of a plurality of ions.

The ion 910 may be provided by an ion source. For example, the ion source may be an ion gun as used in ion milling. Alternatively, the ion source may be an appropriate ion source known in the art. By way of example only, the ion source may be a multi-mode gas cluster ion source as manufactured by Kratos Analytical.

The component 920 may be any component related to a lithographic process (as discussed above). As an example, the component 920 may be a pellicle. The component 920 has a first side 921 and a second side 922. The component is made of atoms such as the atom 923. It should be appreciated that while FIG. 9A depicts a component 920 (and a contaminant 930) with simplified arrangements of atoms, this is merely exemplary and the method depicts in FIG. 9A (and FIG. 9B described below) may be applied to components with more complicated arrangements of atoms.

The second side 922 of the component 920 has been contaminated with a contaminant 930. The contaminant 930 is made of atoms such as the atom 931. A binding force binds atoms of the contaminant 930 that are proximal to the component 920 (such as the atom 932) to the atoms of the component 920. The binding force may be due to, for example, van der Waals forces.

The ion 910 is directed towards the first side 921 of the component 920 in a direction indicated by the arrow 912. In other words, the ion 910 irradiates the first surface 921 of the component 920. The ion may travel through some of the component 920. An intermediate position 914 (and corresponding direction) of the ion 910 is indicated and shows the ion 910 travelling between the atoms on the surface of the first side 921 of the component 920.

The ion 910 collides with a first atom 924 of the component 920 in a first collision 941 (indicated with a star symbol). In the first collision 941, a momentum exchange occurs between the ion 910 and the first atom 924 resulting in the first atom 924 gaining momentum. The first atom 924 gains sufficient momentum to move from the original position of the first atom 924 (e.g. from the lattice site for atoms arranged in a crystal structure). Such movement of the first atom 924 may be referred to as the first atom 924 being ‘ejected.’ In other words, the ion 910 causes a cascade, also referred to as a collision cascade.

The first atom 924 collides with a second atom 925 of the component 920 in a second collision 942. Similar to the first collision 941, in the second collision 942 there is a momentum exchange between the first atom 924 and the second atom 925 resulting in the second atom 925 gaining momentum. The second atom 925 gains sufficient momentum to move from the original position of the second atom 925.

The second atom 925 (of the component 920) collides with an atom 936 of the contaminant 930 in a third collision 943. In the third collision 943, a momentum exchange occurs between the second atom 925 and the atom 936 of the contaminant 930. The atom 936 of the contaminant 930 gains sufficient momentum to move from the original position of the atom 936 (to a position further away from the second surface 922 of the component 920). As a result, the binding forces that attract the atom 936 (and the contaminant 930) to the second surface 922 of the component 920 are reduced.

The contaminant 930 may be sputtered. In other words, due to the reduction in the binding forces, the contaminant 930 may be released from the second side 922 of the component 920. In other examples, the contaminant 930 may not be released and instead may remain on the second side 922 of the component 920 with lower strength binding forces (compared to without/before ion beam sputtering). In examples in which the contaminant 930 is not released due to sputtering, the contaminant 930 may be subsequently removed by the use of other cleaning methods e.g. by the application of heat as described above.

It will be appreciated that while the example of FIG. 9A depicts a cascade of three collisions (i.e. a first collision 941, a second collision 942 and a third collision 943), any number of collisions are possible prior to a collision involving an atom of the contaminant 930 (such as the collision 943). In some examples, the ion 910 may travel directly through the component 920 (i.e. without colliding with any atoms of the component 920) and the ion 910 itself may collide with an atom of the contaminant 930 (such as the atom 936).

It will also be appreciated that the ion 910 may interact with the first surface 921 of the component at any appropriate region (of the first surface 921) using any appropriate angle. For example, the direction 912 of the ion 910 may be perpendicular to the first surface 921 and directed to a region of the first surface 921 that is opposed to a region of the second surface 921 that is contaminated (e.g. by the contaminant 930). As an alternative example, the direction 912 of the ion 910 may be at an alternative angle (i.e. not perpendicular) to the first surface 921 and directed to a region of the first surface 921 such that the ion 910 is directed towards a region of the second surface 921 that is contaminated. In other words, the direction 912 of the ion 910 and the region of the first surface 921 on which the ion is incident may be chosen such that the ion 910 (and any cascades resulting from the ion 910) are directed to the region of the second surface 921 that is contaminated.

While FIG. 9A depicts a single ion 910, it will be appreciated that any appropriate number of ions 910 may be used to achieve a desired cleaning effect (i.e. whether that is removal of the contaminant 930 by sputtering or reduction of the binding forces binding the contaminant 930 to the second side 922 of the component 920). Likewise, properties of the ions 910 may be selected to achieve the desired cleaning effect. For example, the energy of each ion 910 and/or the total dose/current provided by all ions 910 may be selected to achieve the desired cleaning effect. An energy of approximately 0.1 keV to 10 keV may be an appropriate energy for each ion 910. A current of approximately 1 nA to 1 mA may be an appropriate total current. The properties of the ions 910 may be selected to provide enough energy to cause a cascade of atoms within the component 920. The properties of the ions 910 may be selected to prevent damage to the component 920. For example, the properties of the ions 910 may be selected to ensure that a cascade of atoms within the component 920 is of an appropriate size (i.e. an appropriate number of atoms are ejected) to reduce and/or avoid damage to the component 920. Examples of damage that may occur if the properties of the ions 910 are not appropriately selected include a surface of the component 920 becoming textured, the component 920 may be thinned, and/or the structure of the component 920 may be degraded. Such damage may impact the performance of the component 920. In the example in which the component 920 is a pellicle, the damage may negatively impact imaging key performance indicators. The energy of each ion 910 may be selected to ensure that each ion 910 has enough energy to eject a single atom in the component 920.

The first side 921 of the component 920 may be irradiated with ions 910 in one or more regions. For example, a region (of the second side 922 of the component 920) may be identified as contaminated and a corresponding region of the first side 921 may be irradiated by ions 910 to achieve a cleaning effect in the region of the second side 922. The contaminated region may be identified using any appropriate apparatus and/or techniques known in the art, for example, optical apparatus and/or techniques. Additionally or alternatively, multiple regions of the second side 922 may be cleaned by irradiating corresponding regions of the first side 921 in turn. The entire surface of the second side 922 may be cleaned in this way. In other words, the ions 910 (and/or the ion source) may scan across the component 920 in a similar manner as described above in reference to the heater. This may be referred to as a raster scan.

The component 920 may have any coefficient of thermal expansion. In other words, the coefficient of thermal expansion of the component 920 may have no impact on the cleaning by ion irradiation.

FIG. 9B depicts a second schematic diagram of a component related to a lithographic process being cleaned. FIG. 9B depicts a system 902 comprising a component related to a lithographic process 910 which has been contaminated by a contaminant 930. Various aspects of the system 902 (including the component 920 and the contaminant 930) are substantially the same as in the system 901 and are numbered likewise. An ion 950 is irradiating the component 920.

Aside from the direction and starting position, the ion 950 may be substantially the same as the ion 910.

The ion 950 is directed towards the second side 922 of the component 922 (i.e. the side contaminated with the contaminant 930) in a direction indicated by the arrow 952. In other words, the ion 950 irradiates the second surface 922 of the component 920. The direction 952 of the ion 950 may be at a lower angle (measured relate to a plane defined by the second side 922 of the component 920) than the perpendicular angle discussed in relation to the system 901. In other words, the angle may be a glancing angle. Due to the relative thickness of the contaminant 930 compared to the component 920, the ion 950 may not be able to travel through the contaminant 930 (or cause a cascade passing through the contaminant 930). The angle may therefore be low enough to ensure that regions of the contaminant 930 in contact with the component 920 (such as the region occupied by the atoms 932, 938) may be irradiated by the ions 950 (rather than obscured by the contaminant 930 itself). Likewise to the properties of the ions 910 (discussed above in relation to FIG. 9A), the properties of the ions 950 may be selected to achieve the desired cleaning effect and/or to prevent damage to the component 920.

The ion 950 collides with an atom 938 of the contaminant 930 in a collision 961 (indicated with a star symbol). In the collision 961, a momentum exchange occurs between the ion 950 and the atom 938 resulting in the atom 938 gaining momentum and being ejected. As a result, the binding forces that attract the atom 938 (and the contaminant 930) to the second surface 922 of the component 920 are reduced.

Similar to as in the system 901, in the system 902 the contaminant 930 may be sputtered or and/or the strength of the binding forces may be reduced.

Properties of the ions 950 may be selected to provide an optimum cleaning effect and/or to minimise damage to the component 920. For example, the energy of the ion 950 may be selected to ensure a single collision occurs (i.e. such that a single atom of the contaminant 930 is ejected).

For components that have been contaminated on a first side and a second side, the component may be cleaned using a single ion source cleaning the first side as shown in FIG. 9A and the second side as shown in FIG. 9B. Alternatively, the component may be cleaned a first time on a first side as shown in FIG. 9A and the component and/or the ion source may be re-arranged so that the component may be cleaned a second time on a second side as shown in FIG. 9A. Likewise, a component may be cleaned twice using the methods shown in FIG. 9B.

While the cleaning tool 200 has been described above in relation to cleaning of the component 201, the cleaning tool 200 may be used to test a structural integrity of a component. The cleaning tool 200 may therefore also be described as a testing tool 200. The component tested by the testing tool 200 may be a pellicle or any other component relating to a lithographic process. For example, the tool 200 may be used to test the ultimate tensile strength of, for example, a membrane of a pellicle. When used to test the structural integrity of a component 201, the testing tool 200 may be used in an identical or similar way as when used to clean the component 201.

When used to test a structural integrity of the component 201, the thermomechanical vibrations (caused by the heat provided by the radiation 230) may break the component 201 if a structural integrity is below a required value (i.e. a structural integrity threshold). As an example, a membrane of a pellicle may break if the pellicle does not have the required structural integrity. By testing in this way, a component with a structural integrity below a required value (i.e. a deficient component) may be screened. Beneficially, testing in this way may allow identification of deficient components. As a result, testing in this way may avoid installation of deficient components in, for example, a lithographic apparatus, thereby avoiding periods of downtime. In the example in which the component 201 is a pellicle, testing pellicles in this way (and thereby preventing deficient pellicles from being used in a lithographic apparatus) also prevents a deficient pellicle from damaging a reticle in the event the deficient pellicle breaks while in place in a lithographic apparatus.

The thermomechanical vibrations (and the corresponding one or more mechanical waves) may travel across a surface of the component 201. For example, the one or more mechanical waves may test the structural integrity of a pellicle in a corner of a membrane which would not otherwise be tested using prior art methods. Beneficially, the testing tool 200 may be used to screen for deficient components that would otherwise not have been identified. In particular, prior art testing methods may require clamping of the pellicle at corner portions, resulting in a failure to adequately test the corner portions. When testing a pellicle using prior art testing methods, a pellicle frame may also prevent a membrane from fully deforming across the entirety of the membrane. For example, regions close to the pellicle frame may not deform to the same extent other regions of the membrane. As a result, prior art testing methods may fail to adequately test the regions close to the pellicle frame. Presently described techniques allow for testing of structural integrity across the entirety of the pellicle, including corner portions and/or regions close to the pellicle frame. In particular, presently described techniques allow for testing of structural integrity without clamping of corner portions.

The radiation 230 used for testing the structural integrity of the component 201 may have substantially the same properties as the radiation used for cleaning the component 201. Additionally or alternatively, properties of the radiation (used for testing) may be selected to increase or optimise a velocity amplitude of the one or more mechanical waves induced in the component 201. Increasing the velocity amplitude increases a stress amplitude caused by the one or more mechanical waves. As an example, the radiation used for testing by have a narrower slit width than the slit width of the radiation used for cleaning. A narrower slit width may produce waves with a narrower wavelength, a higher frequency and thus a higher maximum velocity amplitude. As a stress amplitude corresponds to the maximum velocity amplitude, decreasing the slit width (compared to a use of the tool for cleaning) may increase the stress amplitude.

Additionally or alternatively, the radiation 230 used for testing the structural integrity of the component 201 may have an increased pulse energy or spot size. Such radiation 230 may increase a power of heat absorbed by the tool and thus be useful for testing the reliability of the component 201.

The cleaning tool 200 may be provided with additional or alternative components to configure the tool for use as a testing tool. For example, the tool 200 may be provided with additional or alternative optical elements.

In some example, a tool 200 may be operated to provide radiation 230 with a first slit width and radiation 230 with a second slit width. For example, the tool 200 may clean a first component by heating the first component with radiation 230 with the first slit width. The tool may then test a component (either the first component or a second component) by heating the component with radiation with the second slit width. The second slit width may be the same, narrower or wider than the first slit width.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). Such apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A cleaning system for cleaning a component related to a lithographic process, the cleaning system comprising:
at least one radiation emitter configured to, in use, irradiate a region of the component so as to:
cause thermomechanical vibrations in the component; and/or
induce sputtering of contaminants present on the component.

2. A system for testing structural integrity of a component related to a lithographic process, the system comprising:
at least one radiation emitter configured to, in use, irradiate a region of the component so as to cause thermomechanical vibrations in the component.

3. (canceled)

4. The system of claim 1, further comprising a holder configured to hold the component.

5. The system of claim 1, wherein the at least one radiation emitter comprises a heater configured to, in use, irradiate a region of the component so as to cause thermomechanical vibrations in the component.

6. The system of claim 5, wherein the heater is a laser.

7. The system of claim 5, wherein radiation provided by the heater has a frequency from within the range of 300 GHz to 4300 THz.

8. The system of claim 5, wherein radiation provided by the heater has an average power selected from between 1 mW and 200 W.

9. The system of claim 5, wherein radiation provided by the heater is pulsed.

10. The system of claim 9, wherein the radiation has a pulse frequency selected from between 1 Hz and 1 MHz.

11.-12. (canceled)

13. The system of claim 5, wherein the heater is configured to provide a plurality of radiation beams.

14. The system of claim 13, wherein the heater comprises a plurality of heaters to generate one or more beams of the plurality of radiation beams.

15. The system of claim 13, wherein the heater comprises one or more beam splitting and/or redirecting optics to generate one or more beams of the plurality of radiation beams.

16. The system of claim 5, as dependent on claim 4, further comprising a plurality of holders, each configured to hold a component of a plurality of components, and wherein the heater is configured to, in use, heat a region of a respective component of the plurality of respective components.

17. (canceled)

18. The system of claim 16, wherein the heater is configured to heat different ones of the plurality of components with different wavelengths.

19. The system of claim 1, wherein the at least one radiation emitter comprises an ion source configured to, in use, irradiate a region of the component with ions so as to induce sputtering of contaminants present on the component.

20. The system of claim 19, wherein the ion source is configured to, in use, irradiate a region of a first side of the component with ions so as to induce sputtering of contaminants present on the first side and/or a second side of the component.

21. (canceled)

22. The system of claim 1, wherein the at least one radiation emitter comprises:
a heater configured to, in use, heat a region of the component so as to cause thermomechanical vibrations in the component; and
an ion source configured to, in use, irradiate a region of the component with ions so as to induce sputtering of contaminants present on the component.

23.-28. (canceled)

29. The system of claim 1, comprising an adjustor to adjust a slit width of the radiation between a first slit width and a second slit width.

30. A method of cleaning a component related to a lithographic process, the method comprising irradiating a region of the component so as to:
induce thermomechanical vibrations in the component; and/or
induce sputtering of contaminants present on the component.

31. A method of testing the structural integrity of a component related to a lithographic processing, the method comprising irradiating a region of the component so as to induce thermomechanical vibrations in the component.

32.-42. (canceled)
